(19) United States
(12) Patent Application Publication
(10) Pub. No.: US 2010/0300533 A1
(43) Pub. Date: Dec. 2, 2010

(54) PHOTOVOLTAIC DEVICE WITH A POLYMERIC MAT AND METHOD OF MAKING THE SAME

(75) Inventors: ZHIYONG XIA, Rockville, MD (US); Daniel W. Cunningham, Mount Airy, MD (US); John H. Wohlgemuth, Ijamsville, MD (US)

Correspondence Address: CAROL WILSON;BP AMERICA INC., MAIL CODE 5 EAST, 4101 WINFIELD ROAD, WARRENVILLE, IL, 60555, US

(73) Assignee: BP CORPORATION NORTH AMERICA INC., WARRENVILLE, IL (US)

(21) Appl. No.: 12/475,939

(22) Filed: Jun. 1, 2009

(51) Int. Cl. H01L 31/0203; H01L 31/18; B32B 37/14

(52) U.S. Cl. 136/259; 156/306.6; 156/267; 257/E31.117

(57) ABSTRACT

This invention relates to a photovoltaic device with a polymeric mat and a method of making a photovoltaic device with a polymeric mat. The photovoltaic device includes a transparent layer for receiving solar energy, and at least one photovoltaic cell disposed below the transparent layer. The photovoltaic device also includes a polymeric mat disposed below the at least one photovoltaic cell, and a backsheet disposed below the polymeric mat. The photovoltaic device also includes an encapsulant bonding the transparent layer, the at least one photovoltaic cell, the polymeric mat, and the backsheet.

### BACKGROUND

1. Technical Field

This invention relates to a photovoltaic device with a polymeric mat and a method of making a photovoltaic device with a polymeric mat.

2. Discussion of Related Art

Photovoltaic devices convert solar energy into electrical energy. Known photovoltaic devices use an encapsulant and a thick backing material to provide electrical insulation, physical integrity, puncture resistance, cut resistance, long term durability, and reliability. However even with the known photovoltaic devices, there remains a need and a desire for photovoltaic devices with back layers that provide improved electrical insulation, physical integrity, puncture resistance, cut resistance, long term durability, and reliability.

### SUMMARY

This invention relates to a photovoltaic device with a polymeric mat and a method of making a photovoltaic device with a polymeric mat. This invention includes a photovoltaic device with back layers having good electrical insulation, physical integrity, puncture resistance, cut resistance, long term durability, and reliability.

According to a first embodiment, this invention includes a photovoltaic device for converting solar energy into electricity. The photovoltaic device includes a transparent layer for receiving solar energy, and at least one photovoltaic cell disposed below the transparent layer. The photovoltaic device also includes a polymeric mat disposed below the at least one photovoltaic cell, and a backsheet disposed below the polymeric mat. The photovoltaic device also includes an encapsulant bonding the transparent layers, the at least one photovoltaic cell, the polymeric mat, and the backsheet.

According to a second embodiment, this invention includes a process for making a photovoltaic device. The process includes the step of providing a transparent layer, and the step of placing a first sheet of encapsulant over at least a portion of the transparent layer. The process also includes the step of placing at least one photovoltaic cell over the first sheet of encapsulant material, and the step of placing a polymeric mat over the at least one photovoltaic cell. The process also includes the step of placing a second sheet of encapsulant over the at least one photovoltaic cell, and the step of placing a backsheet over the second sheet of encapsulant material. The process also includes the step of laminating the photovoltaic device for a sufficient time and a sufficient temperature for sufficient bonding of the first sheet and the second sheet.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention. In the drawings:

FIG. 1 shows an exploded schematic side sectional view of a photovoltaic device, according to one embodiment;

FIG. 2 shows a woven material, according to one embodiment;

FIG. 3 shows a nonwoven material, according to one embodiment;

FIG. 4 shows a molded material, according to one embodiment;

FIG. 5 shows a thermally bonded structure, according to one embodiment;

FIG. 6 shows a physically entangled structure, according to one embodiment;

FIG. 7 shows a chemically cross-linked structure, according to one embodiment;

FIG. 8 shows a graph of peel strength, according to one embodiment;

FIG. 9 shows a graph of wet insulation resistance, according to one embodiment;

FIG. 10 shows a graph of dry insulation resistance, according to one embodiment;

FIG. 11 shows a graph of power change, according to one embodiment;

FIG. 12 shows a graph of fill factor change, according to one embodiment;

FIG. 13 shows a graph of open circuit voltage change, according to one embodiment; and

FIG. 14 shows a graph of short circuit current change, according to one embodiment.

### DETAILED DESCRIPTION

This invention relates to a photovoltaic device with a polymeric mat and a method of making a photovoltaic device with a polymeric mat.

To insure reliability of photovoltaic devices, adhesion strength between encapsulants and backsheets should be maintained even under conditions with increased temperature and/or increased humidity. High adhesion strength can prevent long term environmental attacks and improve the durability as well as reliability of the photovoltaic device. In order to improve the adhesion strength, primers or adhesion promoters may be used in both the encapsulant and/or the backsheet. The adhesion promoters or coupling agents can be any suitable reactive molecules with different functional groups, such as organic silanes. For example, γ-methacryloxypropyltrimethoxysilane can be used as an adhesion promoter for the encapsulant and glycidoxysilane can be used as an adhesion promoter for the backsheet.

Adhesion between the encapsulant and the backsheet can be influenced by reactivity of the adhesion promoters. During a photovoltaic device lamination process, an olefin end of γ-methacryloxypropyltrimethoxysilane can entangle with the ethylene vinyl acetate (encapsulant) since ethylene vinyl acetate includes a polyolefin portion. The silane portion can be hydrolyzed and react with an external surface, such as the backsheet.

One reinforcing material can include bulk glass fibers along with ethylene vinyl acetate and a binder material, such as polyvinyl alcohol. Suitable levels of the binder material can be about 8 percent on a mass basis. The hydroxyl group rich binder material can pre-react with the adhesion promoter in the encapsulant. The reaction of the binder material with the adhesion promoter can consume the adhesion promoter and can reduce bond strength between the encapsulant and the backsheet.

Without being bound by theory of operation and in the presence of organic silanes, a reinforcing material without a binder material, particularly reinforcing materials without hydroxyl groups, can provide increased bond strength between the encapsulant and the backsheet, such as due to a greater amount of adhesion promoter being available for bonding.

According to one embodiment, this invention can include a 100 percent non-woven polyester mat for a photovoltaic device. Since the polyester mat does not contain a hydrophilic binder material, the efficacy of the silane in both the encapsulant and the backsheet may be improved over devices with a binder material. As adhesion between the encapsulant and the backsheet improves, so does photovoltaic device reliability. Additionally, the photovoltaic device can have less yellowing due to the absence of binder materials, improved mechanical properties, improved wet insulation resistance, ease in manufacture, and/or the like.

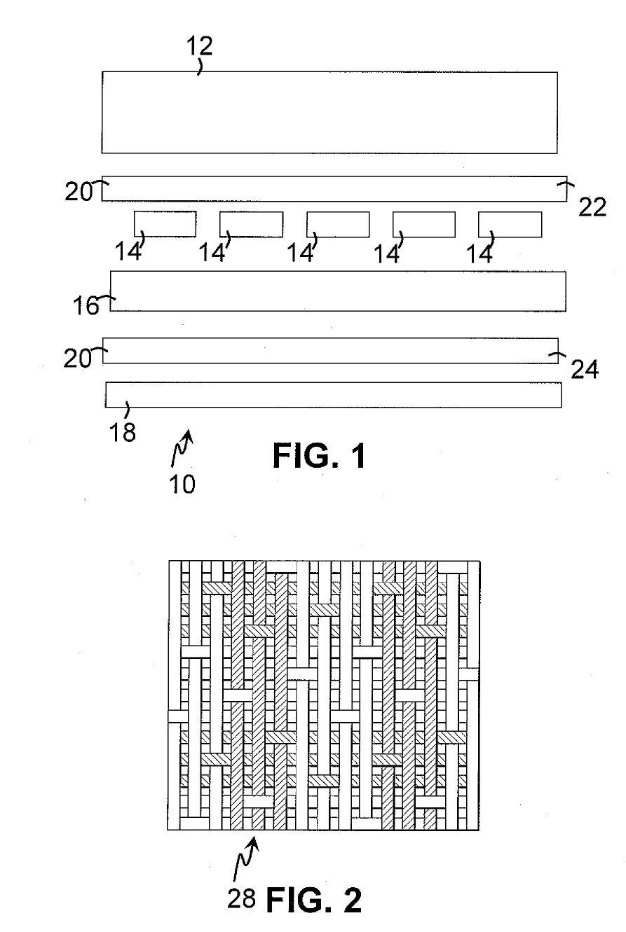

FIG. 1 shows an exploded schematic side sectional view of a photovoltaic device 10, such as during assembly and according to one embodiment. The photovoltaic device 10 includes a transparent layer 12 with a plurality of photovoltaic cells 14 located under the transparent layer 12. The photovoltaic device 10 includes a polymeric mat 16 located under the plurality of photovoltaic cells 14. The photovoltaic device 10 includes a backsheet 18 located under the polymeric mat 16.

An encapsulant 20 binds or laminates the photovoltaic device 10 together, such as including the transparent layer 12, the plurality of photovoltaic cells 14, the polymeric mat 16, and the backsheet 18. The encapsulant 20 includes a first sheet or layer of encapsulant 22 between the transparent layer 12 and the plurality of photovoltaic cells 14. The encapsulant 20 includes a second sheet or layer of encapsulant 24 between the polymeric mat 16 and the backsheet 18.

In the alternative, the second sheet of encapsulant 24 can be between the plurality of photovoltaic cells 14 and the polymeric mat 16. Optionally, the photovoltaic device 10 may include additional layers of encapsulant 20, not shown. Upon lamination the encapsulant 20 may flow and/or fuse through and/or around components of the photovoltaic device 10, such as to no longer form a separate and/or discrete layer as shown in FIG. 1.

FIG. 2 shows a woven material 28, according to one embodiment. The woven material 28 includes a plurality of fibers arranged in an at least generally ordered pattern. Any suitable combination of warp and/or weft can form the woven material 28.

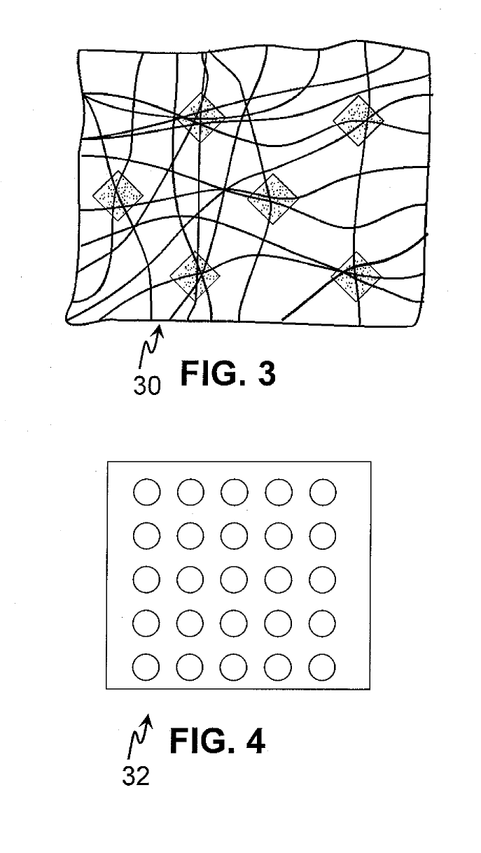

FIG. 3 shows a nonwoven material 30, according to one embodiment. The nonwoven material 30 includes one or more fibers of any suitable length arranged in an at least generally nonordered, random, and/or chaotic pattern. Optionally and/or additionally, the nonwoven material 30 may include an embossed pattern, such as shown as diamonds in FIG. 3.

FIG. 4 shows a molded material 32, according to one embodiment. The molded material 32 can include holes, squares, rectangles, perforations, apertures, dimples, and/or the like of any suitable size and/or shape. The molded part can be from any suitable plastics molding processes, such as compression molding, injection molding, casting, blow molding, and/or the like.

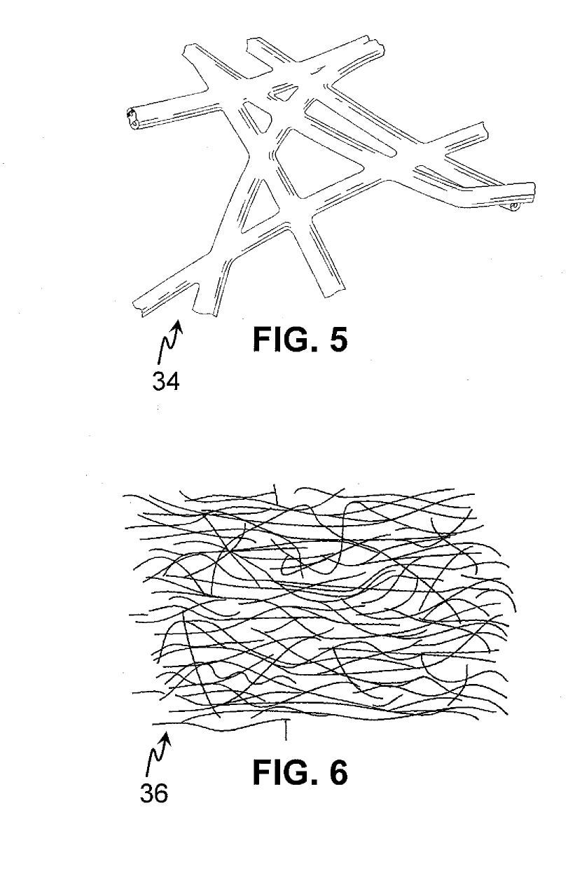

FIG. 5 shows a thermally bonded structure 34, according to one embodiment. The thermally bonded structure 34 can be formed by raising at least a portion of a fiber to and/or above a softening point temperature. The fiber could be formed with components having different melting or softening points.

FIG. 6 shows a physically entangled structure 36, according to one embodiment. The physically entangled structure 36 can be formed by twisting, rolling, and/or the like of one or more fibers.

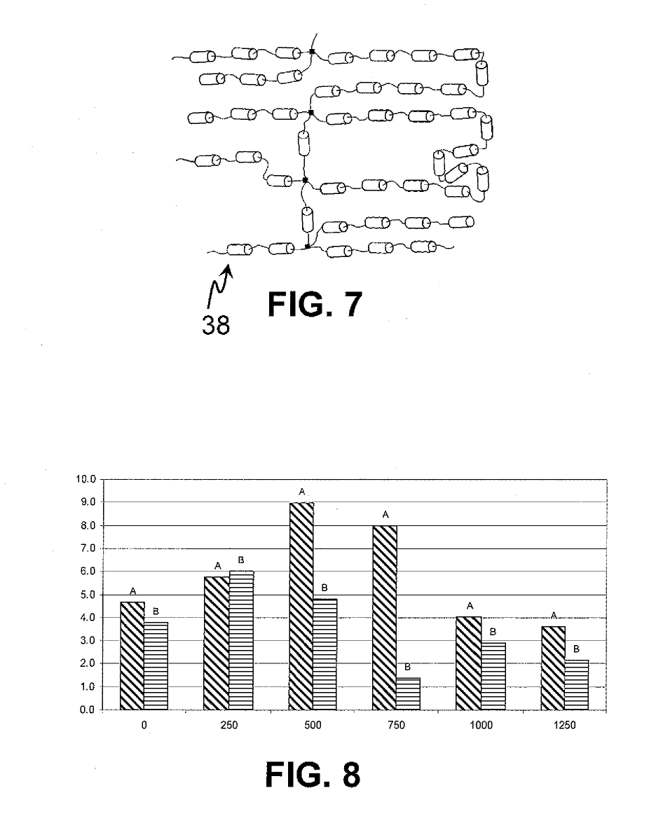

FIG. 7 shows a chemically cross-linked structure 38, according to one embodiment. The cross-linked structure 38 can be formed by reacting any suitable cross-linking agent between one or more fibers.

Photovoltaic devices can convert solar energy or other suitable sources of photons into electricity. Photovoltaic devices broadly can include amorphous silicon, monocrystalline silicon, multicrystalline silicon, near-multicrystalline silicon, geometric multicrystalline silicon, cadmium telluride, copper indium gallium (di)selenide, other suitable photovoltaic materials, and/or the like. Photovoltaic devices may be at least generally rigid and/or at least generally flexible, such as depending on construction techniques and/or fabrication materials. Photovoltaic devices may include solar panels, solar modules, solar arrays, and/or the like.

Solar energy broadly refers to any suitable portion of the electromagnetic spectrum, such as infrared light, visible light, ultraviolet light, and/or the like. Solar energy can come from any suitable source, such as a star and/or the Sun.

According to one embodiment, this invention can include a photovoltaic device for converting solar energy into electricity. The photovoltaic device can include a transparent layer for receiving solar energy, and at least one photovoltaic cell disposed below the transparent layer. The photovoltaic device can include a polymeric mat disposed below the at least one photovoltaic cell, and a backsheet disposed below the polymeric mat. The photovoltaic device can include an encapsulant bonding together and/or laminating the transparent layer, the at least one photovoltaic cell, the polymeric mat, and the backsheet.

Transparent layer broadly refers to a material capable of passing and/or transmitting at least a portion of incoming radiation from the electromagnetic spectrum. According to one embodiment, the transparent layer can pass at least about 60 percent of solar energy contacting a surface of the transparent layer, at least about 80 percent of solar energy contacting a surface of the transparent layer, at least about 90 percent of solar energy contacting a surface of the transparent layer, and/or the like. The transparent layer may include any suitable coatings and/or additives, such as antireflection coatings, ultraviolet filtering additives, and/or the like.

The transparent layer may include any suitable size, shape, and/or material. According to one embodiment, the transparent layer includes polycarbonate, polymethyl methacrylate, glass, and/or the like. The transparent layer can be rigid and/or flexible, for example. Desirably, the transparent layer includes a surface of the photovoltaic device that can receive solar energy, such as at least generally oriented towards the Sun.

At least one broadly refers to more than one, such as at least about 2, at least about 10, at least about 20, at least about 50, at least about 100, and/or the like.

Photovoltaic cell broadly refers to any suitable apparatus for converting photons into electrical power, such as silicon solar cells and/or the like. Photovoltaic cells can be arranged in any suitable configuration, such as in parallel and/or in series to produce a desired voltage level and/or a desired current flow. The photovoltaic device may include any suitable number of photovoltaic cells, such as at least about 1, at least about 10, at least about 36, at least about 72, at least about 144, at least about 250, at least about 500, and/or the like.

Dispose broadly refers to put in place and/or arrange, such as generally physically proximate to each other. Items disposed with respect to each other can have direct physical contact with each other, have indirect physical contact with each other, and/or the like. Items disposed with respect to each other may have intervening materials in between, according to one embodiment.

Below broadly refers to under or beneath and as used in context of the claims can provide a relative position of items and/or layers with respect to each other. Relative positions of materials may be used during fabrication and/or the like, but final positions of materials in an installed photovoltaic device may be different. For example and for ease of manufacture, a transparent layer can be used as a bottom layer or first layer when assembling a photovoltaic device where other materials are placed upon the transparent layer. But upon completion and/or installation, the transparent layer becomes a top layer, such as facing the Sun.

Mat broadly refers to a material used to impart at least some structural, electrical, and/or mechanical properties to a photovoltaic device. The mat may include any suitable manufacturing and/or forming process, such as a cast mat, a molded mat, a blown mat, an extruded, a spun mat, a woven mat, a nonwoven mat, a pleated mat, a felted mat, a knitted mat, a tangled mat, and/or the like. The mat can have any suitable size, shape, and/or color.

In the alternative, the mat may have a laminate structure, such as having more than one material layer and/or strata. The laminate structure may include the mat and the backsheet in a single component for example. Any suitable laminate may be used in the photovoltaic device, such as adhesive bonded laminates, neck bonded laminates, stitch bonded laminates, stretch bonded laminates, thermally bonded laminates, and/or the like.

Polymeric broadly refers any suitable natural, synthetic and/or combination of relatively high molecular weight compound, typically, but not necessarily, including one or more repeating units. Without limitation, types of polymeric materials may include the following and combinations of the following:

(1) polyolefins, such as polyethylene, polypropylene, ethylene and propylene copolymer, polyethylene ionomer, ethylene and ethylene vinyl acetate copolymer, cross-linked polyethylene, and/or the like;

(2) polyesters, such as polyethylene terephthalate, polyethylene naphthalate, polytrimethylene terephthalate, polybutylene terephthalate, polycarbonate, and/or the like;

(3) polyamides, such as nylon and/or the like;

(4) acrylates, such as polymethyl methacrylate, polymethyl acrylate, and/or the like;

(5) elastomers, such as thermoplastic polyurethane, polybutadiene, silicone, polyisoprene, natural rubber, and/or the like;

(6) fluoropolymers, such as polyvinylidene fluoride, polyvinyl fluoride, polytetrafluoroethylene, and/or the like,

(7) biodegradable polymers, such as polylactic acid, polyhydroxybutyrate, polyhydroxyalkanoate, and/or the like;

(8) vinyl polymers, such as polyvinyl chloride, polyvinyl acetate, polyvinyl alcohol, polystyrene, and/or the like;

(9) polysulfones, such as polyether sulfone, polyaryl sulfone, polyphenyl sulfone, and/or the like;

(10) aromatic polyester liquid crystalline polymers and/or the like;

(11) polyethers, such as polyethylene glycol, and/or the like;

(12) polyimides, such as poly(4,4′-oxydiphenylene-pyromellitimide), and/or the like;

(13) polyurethanes, such as containing a urethane linkage, formed by a reaction between a polyisocyanate and a polyol, and/or the like; and

(14) others, such as phenol-formaldehyde resin, miscellaneous thermoplastic resin, thermoset resin, plastomeric material, and/or any other suitable chain-like molecule.

Desirably, the polymeric materials include suitable thermal, mechanical, chemical, and/or electrical properties. Polymeric materials may include suitable filler materials and/or fibers, such as to improve performance.

Backsheet broadly refers to compounds or materials useful for at least a portion of a layer or a cover on a side opposite the transparent layer of the photovoltaic device. The backsheet may be a sheet, a film, a membrane, and/or the like. The backsheet can be flexible and/or rigid. The backsheet can include any suitable material. Desirably, the backsheet includes suitable dielectric properties, such as, for example, to prevent short circuiting and/or allow reliable operation of a photovoltaic device. The backsheet may also provide protection or resistance to water or moisture ingress into the photovoltaic device. According to one embodiment, the backsheet may include a polyester sheet material, such as polyethylene terephthalate optionally with a silane adhesion promoter.

Encapsulant broadly refers to compounds or materials useful for laminating, fusing, adhering, adjoining, gluing, sealing, caulking, bonding, melting, joining, and/or the like at least a portion of components of a photovoltaic device. The encapsulant may bond or laminate the transparent layer, the at least one photovoltaic cell, the polymeric mat, the backsheet, and/or the like into a generally unitary apparatus. The encapsulant may include any suitable materials or compounds, such as ethylene vinyl acetates, ethylene methyl acetates, ethylene butyl acetates, ethylene propylene diene terpolymer, silicones, polyurethanes, thermoplastic olefins, ionomers, acrylics, polyvinyl butyrals, and/or the like. Optionally, the encapsulant may include an adhesion promoter, such as a silane material.

The photovoltaic device may include any suitable layers and/or arrangements of encapsulant materials. For example a single encapsulant layer may provide sufficient lamination for the entire photovoltaic device including the transparent layer, the at least one photovoltaic cell, the polymeric mat, the backsheet, and/or the like. Desirably, but not necessarily, the encapsulant material flows around and/or through materials during the lamination process, such as may allow the encapsulant to contact regions between materials where the solid sheet of encapsulant was not present before lamination.

In the alternative, a first sheet of encapsulant may be disposed between the transparent layer and the at least one photovoltaic cell, and a second sheet of encapsulant may be disposed between the polymeric mat and the backsheet. Other configurations and/or locations of the encapsulant layers for the photovoltaic device are within the scope of this invention.

Bonding broadly refers to joining or securing, such as with physical forces, chemical forces, mechanical forces, and/or like. Suitable chemical forces may include strong forces and/or weak forces, such as ionic bonds, covalent bonds, hydrogen bonds, van der Waals forces, and/or the like. According to one embodiment, bonding includes a suitable amount of cross-linking between functional groups, such as silane molecules of an adhesion promoter.

According to one embodiment, the polymeric mat can include a woven material, a nonwoven material, a molded material, and/or the like. The woven material can have any suitable weave, such as a tight weave with fibers generally abutting or touching each other, a loose weave with holes or gaps between fibers, and/of the like. The nonwoven material can have any suitable arrangement, such as made from continuous fibers, cut fibers, staple fibers, bulk fibers, and/or the like. The molded material can have any suitable characteristics, such as a generally sheet like shape, a perforated sheet, a web, a mesh, a net, and/or the like. Suitable fibers for the polymeric mat can include straight fibers, mechanically crimped fibers, thermally crimped fibers, and/or the like.

The polymeric mat may include any suitable open area, such as about zero percent, between about zero and about 3 percent, between about 2 percent and about 10 percent, less than about 40 percent, at least 40 percent, and/or the like.

Portions of the polymeric mat may be at least generally nonporous and/or impermeable, such as to not allow encapsulant to flow through the polymeric mat. Optionally and/or alternatively, portions of the polymeric mat may be at least generally porous and/or permeable, such as to allow encapsulant to flow through the polymeric mat.

According to one embodiment, the polymeric mat can include a thermally bonded structure, a physically entangled structure, a chemically cross-linked structure, and/or the like. The thermally bonded structure may be made with any suitable process and/or equipment, such as hot air, calendaring rolls, and/or the like. The physically entangled structure may be made with any suitable process and/or equipment, such as water jets, mechanical devices, and/or the like. The chemically cross-linked structure may be made with any suitable process and/or equipment, such as a cross-linking agent with a reactive linkage and/or group. Reactive linkages may include a double bond and/or the like.

The same types and/or different types of materials may be combined to form the mat, such as two or more different fibers types. In the alternative, the fibers for the mat may include multicomponent fibers, such as bicomponent fibers with two polymers spun into the same fiber each with different physical properties.

According to one embodiment, the polymeric mat can include polyesters, polysulfones, polyolefins, liquid crystalline polymers, polyvinyl alcohols, polyvinyl chlorides, phenol-formaldehyde resins, acrylics, polyethers, polyamides, polystyrenes, polyimides, fluoropolymers, polyurethanes, and/or the like.

The polymeric mat can include a nonwoven polyester material, such as polyethylene terephthalates, polybutylene terephthalates, polytrimethylene terephthalates, polyethylene naphthalates, and/or the like, according to one embodiment.

A polymeric mat material may include any suitable physical properties, such as basis weight, caliper, density, tensile strength, elongation, edge tear, porosity, melting point, softening point, glass transition temperature, and/or the like.

According to one embodiment, the polymeric mat material can have a melting point or a softening point of greater than a process temperature of the encapsulant, of at least about 2 degrees Celsius greater than a process temperature of the encapsulant, of at least about 5 degrees Celsius greater than a process temperature of the encapsulant, of at least about 10 degrees Celsius greater than a process temperature of the encapsulant, of at least about 15 degrees Celsius greater than a process temperature of the encapsulant, and/or the like. The process temperature of the encapsulant may be the temperature used for lamination, cross-linking, and/or the like.

In the alternative, the polymeric mat material mat may have a melting point of at least about 150 degrees Celsius, at least about 200 degrees Celsius, at least about 240 degrees Celsius, and/or the like.

According to one embodiment, the polymeric mat excludes a binder material, such as poly vinyl alcohol and/or the like.

The photovoltaic device may meet and/or exceed any suitable industry standard and/or test, such as for safety, reliability, performance, and/or the like. According to one embodiment, the photovoltaic device can have no dielectric breakdown or surface tracking when measured according to a dielectric withstand test as defined in IEC 61730 (part 2, 2004 edition) under a minimum of 6000 volts. Optionally and/or alternatively, the photovoltaic device can have a measured wet insulation resistance times an area of the photovoltaic device at least above 40 megaohms meter squared when measured at 1000 volts as defined in IEC 61215 (2005 edition). The entire teachings of IEC 61730 (part 2, 2004 edition) and IEC 61215 (2005 edition) are hereby incorporated by reference into this specification.

IEC refers to the International Electrotechnical Commission with a Central Office in Geneva Switzerland.

According to one embodiment, the photovoltaic device can have a wet insulation resistance tested at 1000 volts of at least 40 megaohms meter squared after aging for about 1000 hours under about 85 degrees Celsius and about 85 percent relative humidity as defined in IEC 61215 (2005 edition).

According to one embodiment, the photovoltaic device can have a suitable cut resistance and/or puncture resistance. Particularly, the photovoltaic device can pass the Cut Susceptibility Test, MST 12, as defined in IEC 61730 part 2, section 10.3.

According to one embodiment, this invention may include a process for making a photovoltaic device. The process may include the step of providing a transparent layer, and the step of placing a first sheet of encapsulant over at least a portion of the transparent layer. The process may include the step of placing at least one photovoltaic cell over the first sheet of encapsulant material, and the step of placing a polymeric mat over the at least one photovoltaic cell. The process may include the step of placing a second sheet of encapsulant over the at least one photovoltaic cell, and the step of placing a backsheet over the second sheet of encapsulant material. The process may include the step of laminating the photovoltaic device for a sufficient time and/or a sufficient temperature for sufficient bonding of the first sheet and/or the second sheet to the other materials.

A sufficient time and/or a sufficient temperature can vary with different materials, different thicknesses, and/or the like. A sufficient time may include any suitable amount or duration, such as between about 1 minute and 1 hour, between about 2 minutes and about 40 minutes, less than about 15 minutes, and/or the like. A sufficient temperature may include any suitable amount or temperature, such as between about 100 degrees Celsius and about 500 degrees Celsius, between about 100 degrees Celsius and about 180 degrees Celsius, and/or the like.

Sufficient bonding may include any suitable strength and/or cross-linking. For example, a photovoltaic device may include a 90 degree peel strength between the backsheet and the encapsulant of at least about 3 kilograms per linear centimeter after aging for about 500 hours under about 85 degrees Celsius and about 85 percent relative humidity, of at least about 8 kilograms per linear centimeter after aging for about 500 hours under about 85 degrees Celsius and about 85 percent relative humidity, of at least about 12 kilograms per linear centimeter after aging for about 500 hours under about 85 degrees Celsius and about 85 percent relative humidity, and/or the like. For example, a photovoltaic device may include cross-linking between the encapsulant and the backsheet of at least about 50 percent of the cross-linking functional groups, at least about 70 percent of the cross-linking functional groups, at least about 90 percent of the cross-linking functional groups, and/or the like.

Lamination and/or melting may also include the use of pressure and/or force, such as from a mechanical press and/or rolls. Lamination may also include the use of vacuum, such as to assist in removal of moisture, volatiles, air, gases, and/or the like from the photovoltaic device. Vacuum broadly refers to reduced pressure, such as less than atmospheric pressure, less than about 8 centimeters of mercury absolute, and/or the like.

According to one embodiment, the polymeric mat used in the process can include a woven material, a nonwoven material, a molded material, and/or the like. Additionally and/or optionally, the polymeric mat used in the process can include a thermally bonded structure, a physically entangled structure, a chemically cross-linked structure, and/or the like.

According to one embodiment, the polymeric mat used in the process can include polyesters, polysulfones, polyolefins, liquid crystalline polymers, polyvinyl alcohols, polyvinyl chlorides, phenol-formaldehyde resins, acrylics, polyethers, polyamides, polystyrenes, polyimides, fluoropolymers, polyurethanes, and/or the like.

According to one embodiment, the polymeric mat used in the process can be a nonwoven polyester.

The process of making the photovoltaic device can include the step of trimming excess polymeric mat from at least one edge of the solar panel, according to one embodiment. Generally, a mat material can desirably provide an exit path for air or gases during the lamination process, such as to reduce entrained bubbles which can reduce peel strength. However for some wicking mat materials, the same path for gas exit can be a path for water or moisture ingression which can delaminate packaging materials of the photovoltaic device and/or corrode materials. Photovoltaic device manufactures can trim the mat material (for example, fiberglass) to be smaller than the transparent layer before lamination and use care when assembling the photovoltaic device to prevent the mat material from extending to the edge of the transparent layer (fully encapsulating the fiberglass mat).

The polymeric mat materials described herein can be at least somewhat hydrophobic and reduce wicking of moisture into the photovoltaic device. Accordingly, a high reliability photovoltaic device can be made with excess mat material (to allow better off gassing and without alignment steps), where the excess mat material can be trimmed after lamination (not fully encapsulating the polymeric mat).

The first sheet of encapsulant and the second sheet of encapsulant can comprise the same and/or different types of material, according to one embodiment. Optionally, the polymeric mat can be impregnated with encapsulant ahead of time, such as to reduce a number of layers used during fabrication.

According to one embodiment, this invention may include a photovoltaic device made by any of the processes disclosed herein. Desirably, the photovoltaic device made by the processes disclosed herein can have no dielectric breakdown or surface tracking when measured according to a dielectric withstand test as defined in IEC 61730 (part 2, 2004 edition) under a minimum of 6000 volts, and a measured wet insulation resistance times an area of the photovoltaic device at least about 40 megaohms meter squared when measured at 1000 volts as defined in IEC 61215 (2005 edition). Also desirably, the photovoltaic device made by the processes disclosed herein can have wet insulation resistance tested at 1000 volts of at least 40 megaohms meter squared after aging for about 1000 hours under about 85 degrees Celsius and about 85 percent relative humidity as defined in IEC 61215 (2005 edition).

### EXAMPLES

### Example 1

A nonwoven polyethylene terephthalate mat was laminated into a mock photovoltaic device without photovoltaic cells, according to one embodiment. The nonwoven polyethylene terephthalate mat contains no binder material with hydroxyl functional groups so a potential reaction between hydroxyl groups and an adhesion promoter is reduced. Put another way, since there is no binder material to consume a portion of the adhesion promoter, all of the adhesion promoter can react to improve adhesion between the encapsulant and the backsheet.

The nonwoven polyethylene terephthalate mat had a basis weight of 34 grams per meter squared, and a density of 0.146 grams per cubic centimeter. The nonwoven polyethylene terephthalate mat had a tensile strength of 31 newtons per 25 millimeters in a machine direction and 18 newtons per 25 millimeters in a transverse direction. The nonwoven polyethylene terephthalate mat had a porosity of 6498 liters per meter squared per second at 200 pascals.

The mock photovoltaic device was assembled using a glass transparent layer, a first layer of ethylene vinyl acetate encapsulant, the nonwoven polyethylene terephthalate mat, a second layer of ethylene vinyl acetate encapsulant, and a polyester backsheet. Both the encapsulant and the backsheet each included silane adhesion promoters or primers. The mock photovoltaic device was laminated to activate or cure the encapsulant layers. FIG. 8 shows a graph of peel strength in kilograms per centimeter of the mock photovoltaic device with the nonwoven polyethylene terephthalate mat (A), according to one embodiment. The mock photovoltaic device was tested at 85 degrees Celsius and 85% relative humidity for 1250 hours.

### Comparative Example 1

A mock photovoltaic device was prepared as in Example 1 except the polyethylene terephthalate mat was replaced with a nonwoven fiberglass mat. FIG. 8 shows a graph of peel strength in kilograms per centimeter of the mock photovoltaic device with the nonwoven fiberglass mat (B) at the conditions described in Example 1.

The nonwoven fiberglass mat had a basis weight of 22.5 grams per meter squared according to TAPPI T-1011, and an apparent density of 0.18 grams per cubic centimeter according to ASTM D1505. The nonwoven fiberglass mat had a tensile strength of 28 newtons per 25 millimeters in a machine direction and 16 newtons per 25 millimeters in a transverse direction. The nonwoven fiberglass mat had a porosity of 4982 liter per meter squared per second at 200 pascals.

FIG. 8 shows an improvement of almost double the peel strength of the encapsulant to backsheet adhesion between the two mock photovoltaic devices at 500 hours. Even more surprising and unexpected, the graph shows a more than fourfold increase in peel strength at 750 hours.

### Example 2

A photovoltaic device was made having the structure of a glass layer, a first layer of ethylene vinyl acetate encapsulant, 72 silicon photovoltaic cells, a nonwoven polyester mat, a second layer of ethylene vinyl acetate encapsulant (with the same composition as the first layer of encapsulant), and a polyester backsheet. The nonwoven polyester mat touched or reached the edge of the glass layer, such as to not fully encapsulate the nonwoven polyester mat.

### Comparative Example 2A

A photovoltaic device was made according to Example 2 except the nonwoven polyester mat was replaced with a nonwoven fiberglass mat. The nonwoven fiberglass mat touched or reached the edge of the glass layer, such as to not fully encapsulate the nonwoven fiberglass mat.

### Comparative Example 2B

A photovoltaic device was made according to Example 2 except the nonwoven polyester mat was replaced with a nonwoven fiberglass mat The nonwoven fiberglass was sized about 15 millimeters smaller than the edge of the glass layer and did not touch or reach the edge of the glass layer, such as to fully encapsulate the nonwoven fiberglass mat.

### Discussion of Example 2 Results

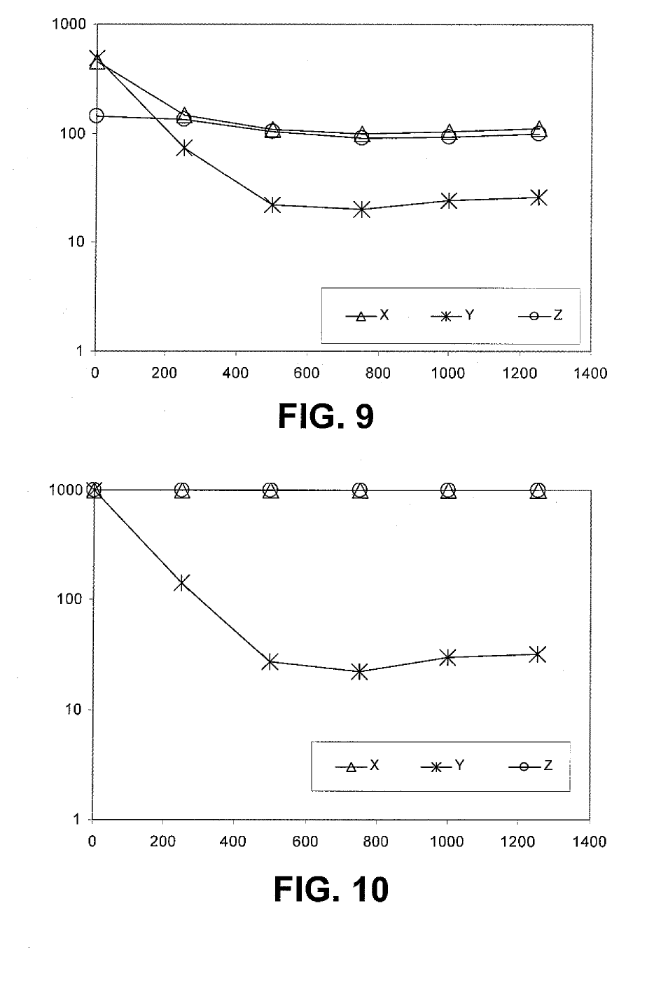

FIG. 9 shows a graph of wet insulation resistance in megaohms meter squared at 1 kilovolt on a logarithmic scale for up to 1250 hours of damp heat for the photovoltaic devices of Example 2 (X), Comparative Example 2A (Y), and Comparative Example 2B (Z). FIG. 9 shows the photovoltaic device of Comparative Example 2A fails after 500 hours of the damp heat test. IEC 61215 (2005 edition) provides a minimum wet insulation resistance at 1 kilovolt of 40 megaohms meter squared for a passing device. The photovoltaic devices of Example 2 and Comparative Example 2B have similar wet insulation performance. Therefore, the photovoltaic device with the polyester mat extending to the edge of the glass has a wet insulation resistance like the photovoltaic device with the fully encapsulated fiberglass mat.

FIG. 10 shows a graph of dry insulation resistance in megaohms meter squared at 1 kilovolt on a logarithmic scale for up to 1250 hours of damp heat for the photovoltaic devices of Example 2 (X), Comparative Example 2A (Y), and Comparative Example 2B (Z). Similarly, the photovoltaic device of Comparative Example 2A failed after 500 hours, but the photovoltaic devices of Example 2 and Comparative Example 2B had dry insulation resistance values of greater than 1000 megaohms meter squared.

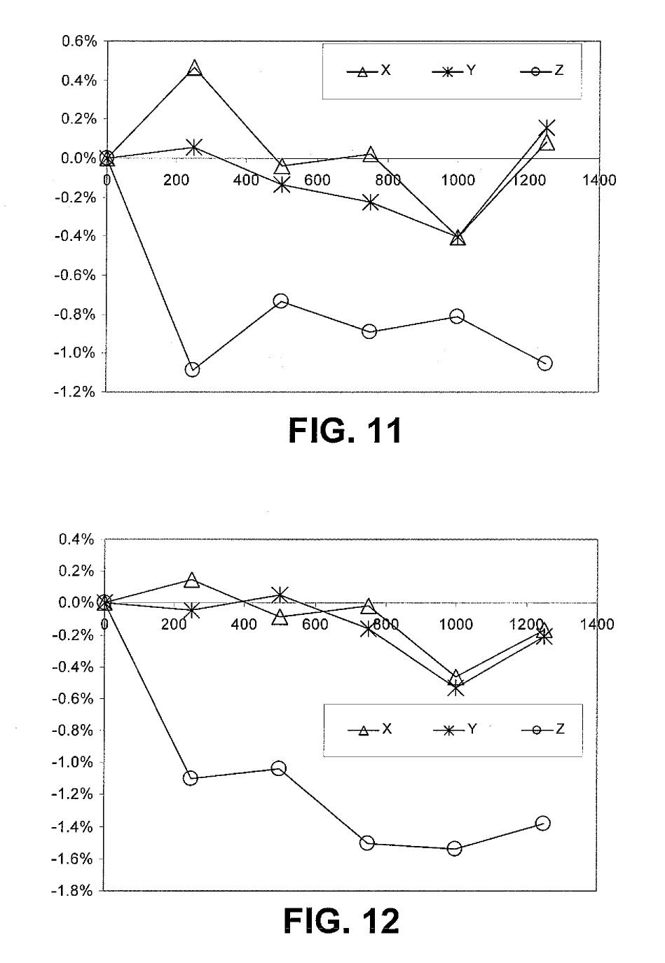

FIG. 11 shows a graph of power change in percent for up to 1250 hours of damp heat for the photovoltaic devices of Example 2 (X), Comparative Example 2A (Y), and Comparative Example 2B (Z).

FIG. 12 shows a graph of fill factor change in percent for up to 1250 hours of damp heat for the photovoltaic devices of Example 2 (X), Comparative Example 2A (Y), and Comparative Example 2B (Z).

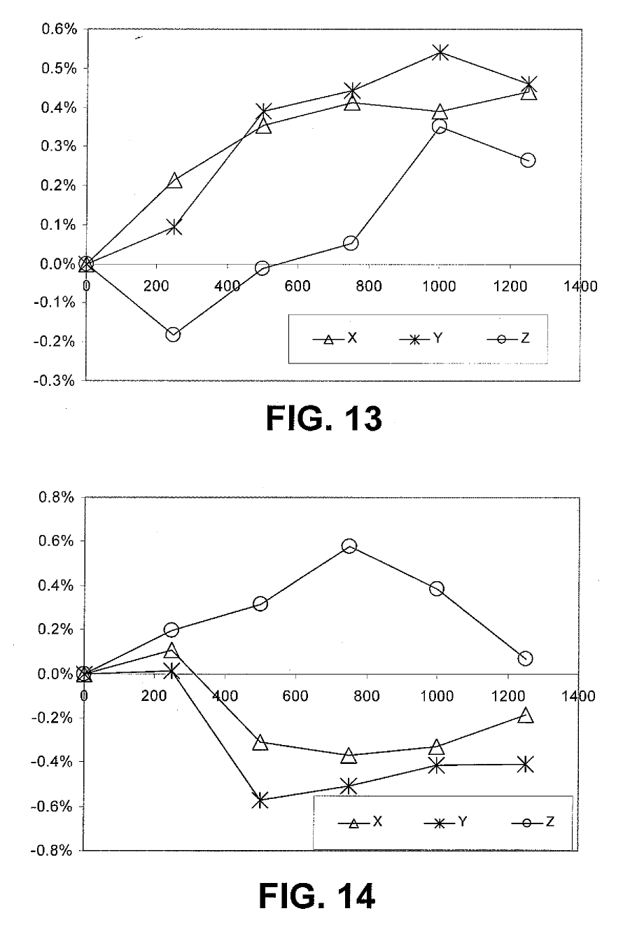

FIG. 13 shows a graph of open circuit voltage change in percent for up to 1250 hours of damp heat for the photovoltaic devices of Example 2 (X), Comparative Example 2A (Y), and Comparative Example 2B (Z).

FIG. 14 shows a graph of short circuit current change in percent for up to 1250 hours of damp heat for the photovoltaic devices of Example 2 (X), Comparative Example 2A (Y), and Comparative Example 2B (Z).

In summary, FIGS. 11-14 show the photovoltaic devices of Example 2 (X), Comparative Example 2A (Y), and Comparative Example 2B (Z) all passed the electrical performance tests according to IEC 61215 (2005 edition).

As used herein the terms “having”, “comprising”, and “including” are open and inclusive expressions. Alternately, the term “consisting” is a closed and exclusive expression. Should any ambiguity exist in construing any term in the claims or the specification, the intent of the drafter is toward open and inclusive expressions.

Regarding an order, number, sequence, and/or limit of repetition for steps in a method or process, the drafter intends no implied order, number, sequence and/or limit of repetition for the steps to the scope of the invention, unless explicitly provided.

Regarding ranges, ranges are to be construed as including all points between the upper and lower values, such as to provide support for all possible ranges contained between the upper and lower values including ranges with no upper bound and/or lower bound.

It will be apparent to those skilled in the art that various modifications and variations can be made in the disclosed structures and methods without departing from the scope or spirit of the invention.

Particularly, descriptions of any one embodiment can be freely combined with descriptions or other embodiments to result in combinations and/or variations of two or more elements or limitations. Other embodiments of the invention will be apparent to those skilled in the art from consideration of the 5 specification and practice of the invention disclosed herein. It is intended that the specification and examples be considered exemplary only, with a true scope and spirit of the invention being indicated by the following claims.

What is claimed is:

1. A photovoltaic device for converting solar energy into electricity, the photovoltaic device comprising:
a transparent layer for receiving solar energy;
at least one photovoltaic cell disposed below the transparent layer;
a polymeric mat disposed below the at least one photovoltaic cell;
a backsheet disposed below the polymeric mat; and
an encapsulant bonding the transparent layer, the at least one photovoltaic cell, the polymeric mat, and the backsheet.

2. The photovoltaic device of claim 1, wherein the polymeric mat comprises a woven material, a nonwoven material, or a molded material.

3. The photovoltaic device of claim 1 wherein the polymeric mat comprises a thermally bonded structure, a physically entangled structure, or a chemically cross-linked structure.

4. The photovoltaic device of claim 1, wherein the polymeric mat comprises polyesters, polysulfones, polyolefins, liquid crystalline polymers, polyvinyl alcohols, polyvinyl chlorides, phenol-formaldehyde resins, acrylics, polyethers, polyamides, polystyrenes, polyimides, fluoropolymers, polyurethanes, or combinations thereof.

5. The photovoltaic device of claim 1, wherein the polymeric mat comprises a nonwoven polyester material.

6. The photovoltaic device of claim 5, wherein the polyester material comprises polyethylene terephthalates, polybutylene terephthalates, polytrimethylene terephthalates, polyethylene naphthalates, or combinations thereof.

7. The photovoltaic device of claim 1, wherein a material of the polymeric mat has a melting point or a softening point greater than a process temperature of the encapsulant.

8. The photovoltaic device of claim 1, wherein the polymeric mat excludes a binder material.

9. The photovoltaic device of claim 1, wherein the encapsulant comprises ethylene vinyl acetates, ethylene methyl acetates, ethylene butyl acetates, ethylene propylene diene terpolymer, silicones, polyurethanes, thermoplastic olefins, ionomers, acrylics, polyvinyl butyrals, or combinations thereof.

10. The photovoltaic device of claim 1, wherein the photovoltaic device has:
no dielectric breakdown or surface tracking when measured according to a dielectric withstand test as defined in IEC 61730 (part 2, 2004 edition) under a minimum of 6000 volts; and
a measured insulation resistance times an area of the photovoltaic device at least about 40 megaohms meter squared when measured at 1000 volts as defined in IEC 61215 (2005 edition).

11. The photovoltaic device of claim 1, wherein the photovoltaic device has a wet insulation resistance tested at 1000 volts of at least 40 megaohms meter squared after aging for about 1000 hours under about 85 degrees Celsius and about 85 percent relative humidity as defined in IEC 61215 (2005 edition).

12. A process for making a photovoltaic device, the process comprising:
providing a transparent layer;
placing a first sheet of encapsulant over at least a portion of the transparent layer;
placing at least one photovoltaic cell over the first sheet of encapsulant material;
placing a polymeric mat over the at least one photovoltaic cell;
placing a second sheet of encapsulant over the at least one photovoltaic cell;
placing a backsheet over the second sheet of encapsulant material; and
laminating the photovoltaic device for a sufficient time and a sufficient temperature for sufficient bonding of the first sheet and the second sheet.

13. The process of claim 12, wherein the polymeric mat comprises:
a woven material, a nonwoven material, or a molded material; and
a thermally bonded structure, a physically entangled structure, or a chemically cross-linked structure.

14. The process of claim 12, wherein the polymeric mat comprises polyesters, polysulfones, polyolefins, liquid crystalline polymers, polyvinyl alcohols, polyvinyl chlorides, phenol-formaldehyde resins, acrylics, polyethers, polyamides, polystyrenes, polyimides, fluoropolymers, polyurethanes, or combinations of thereof.

15. The process of claim 12, wherein the polymeric mat comprises a nonwoven polyester.

16. The process of claim 12, further comprising trimming excess polymeric mat from at least one edge of the solar panel.

17. The process of claim 12, wherein the first sheet of encapsulant and the second sheet of encapsulant comprise the same type of material.

18. A photovoltaic device made by the process of claim 12.

19. The photovoltaic device of claim 18, wherein the photovoltaic device has:
no dielectric breakdown or surface tracking when measured according to a dielectric withstand test as defined in IEC 61730 (part 2, 2004 edition) under a minimum of 6000 volts; and
a measured wet insulation resistance times an area of the photovoltaic device at least about 40 megaohms meter squared when measured at 1000 volts as defined in IEC 61215 (2005 edition).

20. The photovoltaic device of claim 18, wherein the photovoltaic device has a wet insulation resistance tested at 1000 volts of at least 40 megaohms meter squared after aging for about 1000 hours under about 85 degrees Celsius and about 85 percent relative humidity as defined in IEC 61215 (2005 edition).
